(19) United States
(12) Patent Application Publication
(10) Pub. No.: US 2023/0207418 A1
(43) Pub. Date: Jun. 29, 2023

(54) SEMICONDUCTOR MODULE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: MASAYUKI KAMIYA, Nisshin-shi (JP)

(21) Appl. No.: 18/054,299

(22) Filed: Nov. 10, 2022

(30) Foreign Application Priority Data
Dec. 23, 2021 (JP) 2021-209678

(51) Int. Cl. H01L 23/373; H01L 23/31

(52) U.S. Cl. CPC H01L 23/3735; H01L 23/3121; H01L 24/32; H01L 2224/32245

(57) ABSTRACT

A semiconductor module includes an insulating plate, a graphite plate and a semiconductor element. The graphite plate is provided by a stack of graphene layers. The graphite plate has a first surface joined to the insulating plate, and a second surface opposite to the first surface. The semiconductor element is disposed adjacent to the second surface of the graphite plate. The insulating plate extends from the graphite plate in a plan view in a direction normal to the graphite plate.

### CROSS REFERENCE TO RELATED APPLICATION

The present application claims the benefit of priority from Japanese Patent Application No. 2021-209678 filed on Dec. 23, 2021. The entire disclosures of the above application are incorporated herein by reference.

### TECHNICAL FIELD

The present disclosure relates to a semiconductor module.

### BACKGROUND

For example, there is a semiconductor module that is disposed on a cooler, and includes an insulating plate, a graphite plate and a semiconductor element. The graphite plate is bonded to the insulating plate. The semiconductor element is mounted on a surface of the graphite plate opposite to the surface bonded to the insulating plate. The semiconductor module is used in a state where the insulating plate is in contact with the cooler.

### SUMMARY

The present disclosure describes a semiconductor module including an insulating plate, a graphite plate and a semiconductor element. The graphite plate may be provided by a stack of graphene layers, and have a first surface joined to the insulating plate and a second surface opposite to the first surface. The semiconductor element is disposed adjacent to the second surface of the graphite plate. The insulating plate extends from the graphite plate in a plan view in a direction normal to the graphite plate.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a diagram schematically showing a cross-sectional view of a main part of a semiconductor module; and

FIG. 2 is a diagram schematically showing an exploded perspective view of an insulating plate and a graphite plate, in which an illustration of a brazing material is omitted for clarity of illustration.

### DETAILED DESCRIPTION

To begin with, a relevant technology will be described only for understanding the embodiments of the present disclosure. For example, there is a semiconductor module disposed on a cooler and including an insulating plate, a graphite plate bonded to the insulating plate, and a semiconductor element mounted on a surface of the graphite plate opposite to the surface bonded to the insulating plate. The semiconductor module may be used in a state where the insulating plate is in contact with the cooler. Heat generated in accordance with an operation of the semiconductor element may be efficiently transferred to the cooler via the graphite plate. The insulating plate may be provided in order to ensure electrical insulation between the graphite plate and the cooler.

In such a semiconductor module, if the insulating plate and the graphite plate have the same dimensions in a plan view, that is, when viewed in a direction normal to the insulating plate, there is a concern that current may flow from the graphite plate to the cooler due to a creepage leak current along the insulating plate.

According to an aspect of the present disclosure, a semiconductor module includes an insulating plate, a graphite plate and a semiconductor element. The graphite plate is provided by a stack of graphene layers. The graphite plate has a first surface and a second surface opposite to the first surface. The first surface of the graphite plate is joined to the insulating plate. The semiconductor element is disposed adjacent to the second surface of the graphite plate. The insulating plate extends from the graphite plate in a plan view in a direction normal to the graphite plate.

In such a semiconductor module, since a creepage distance at the insulating plate is kept long, a creepage leak current along the insulating plate can be suppressed.

An embodiment of the present disclosure will be described hereinafter with reference to the drawings.

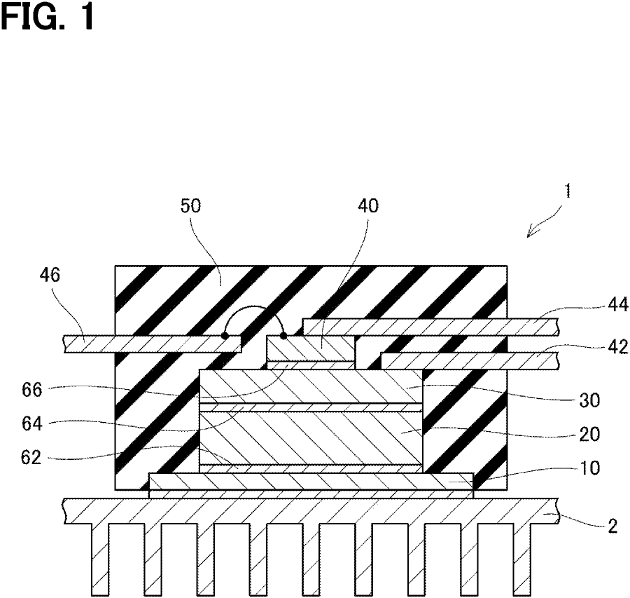

As shown in FIG. 1, a semiconductor module 1 includes an insulating plate 10, a graphite plate 20, a metal plate 30, a semiconductor element 40 and a molded resin 50. The semiconductor module 1 is used in a state of being arranged on a water-cooled or air-cooled cooler 2. As an example, the semiconductor module 1 is configured as a single-side cooling type. As another example, the semiconductor module 1 may be configured as a double-side cooling type.

The insulating plate 10 is a plate-shaped member having an insulating property. Although not particularly limited, the insulating plate 10 may be, for example, a ceramic plate made of such as aluminum nitride (AIN) or aluminum oxide (Al₂O₃). The insulating plate 10 is covered with the molded resin 50 in such a manner that a side surface and a part of an upper surface of the insulating plate 10 are covered with the molded resin 50 and only a surface facing the cooler 2 is exposed from the molded resin 50. The insulating plate 10 and the cooler 2 are in contact with each other through grease. As another example, the insulating plate 10 and the cooler 2 may be brazed to each other through a brazing material.

The graphite plate 20 is a plate-shaped member. The graphite plate 20 is disposed between the insulating plate 10 and the metal plate 30, and is joined to each of the insulating plate 10 and the metal plate 30. In this case, “joined to” or “joining” means a fixed state in which two base materials are fixed physically and/or chemically. The two base materials may be joined by direct contact, or may be joined via another member. In this example, the graphite plate 20 and the insulating plate 10 are brazed through a brazing material 62, and the graphite plate 20 and the metal plate 30 are brazed through a brazing material 64. The brazing materials 62 and 64 are not particularly limited, but may be made of silver (Ag) or copper (Cu), for example.

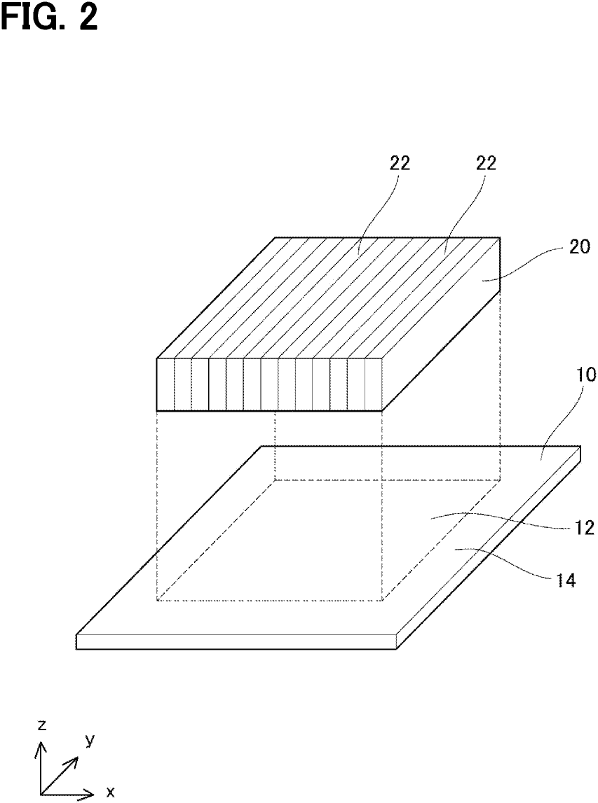

FIG. 2 shows an exploded perspective view of the main parts of the insulating plate 10 and the graphite plate 20. In FIG. 2, a z-axis direction corresponds to a stacking direction in which the insulating plate 10 and the graphite plate 20 are stacked, and also corresponds to a thickness direction of the insulating plate 10 and a direction normal to the insulating plate 10. Also, an x-axis direction is a direction orthogonal to the z-axis direction, and a y-axis direction is a direction orthogonal to both the z-axis direction and the x-axis direction. The graphite plate 20 is a plate-shaped member extending along an xy plane, that is, having a planar direction along the xy plane.

The graphite plate 20 is provided by a stacked body of multiple graphene layers 22. The graphene layers 22 are stacked in the x-axis direction. The graphene layer 22 has a thermal conductivity anisotropy, and the thermal conductivity in a planar direction parallel to the yz plane is higher than the thermal conductivity in the x-axis direction (i.e., the stacking direction of the multiple graphene layers 22). In the graphite plate 20, the stacking direction (x-axis direction) of the multiple graphene layers 22 is referred to as a c-axis direction, and the direction orthogonal to the c-axis direction is referred to as an a-axis direction. The graphite plate 20 is disposed so that the a-axis direction of the graphite plate 20 is parallel to the stacking direction of the insulating plate 10 and the graphite plate 20 (i.e., the z-axis direction). In other words, the graphite plate 20 is disposed so that the a-axis direction is parallel to a direction connecting the cooler 2 and the semiconductor element 40 (see FIG. 1). As such, heat generated from the semiconductor element 40 when the semiconductor element 40 is operated is efficiently transferred to the cooler 2 via the graphite plate 20.

As described above, the graphite plate 20 is brazed to the insulating plate 10 through the brazing material 62. Here, a portion of the insulating plate 10 to which the graphite plate 20 is joined is referred to as a joining portion 12. The insulating plate 10 has an extension portion 14 around the joining portion 12. The extension portion 14 of the insulating plate 10 is a portion extending from the graphite plate 20 in a plan view when viewed in the z-axis direction, that is, in a plan view in the normal direction to the insulating plate 10. The extending portion 14 of the insulating plate 10 is provided so as to entirely surround an outer periphery of the graphite plate 20.

As shown in FIG. 1, the metal plate 30 is a plate-shaped member, and is disposed between the graphite plate 20 and the semiconductor element 40. The metal plate 30 is joined to each of the graphite plate 20 and the semiconductor element 40. The metal plate 30 and the graphite plate 20 are brazed through the brazing material 64, and the metal plate 30 and the semiconductor element 40 are joined through a solder 66. The material of the metal plate 30 is not particularly limited, but may be copper, for example. The metal plate 30 allows an electric current, which occurs when the semiconductor element 40 is turned on, to expand in the planar direction and to flow to the graphite plate 20.

The semiconductor element 40 is mounted on a surface of the graphite plate 20 through the metal plate 30, the surface being opposite to the surface of the graphite plate 20 joined to the insulating plate 10. The semiconductor element 40 is a vertical switching element. Although not particularly limited, the semiconductor element 40 may be, for example, a metal oxide semiconductor field effect transistor (MOSFET) or an insulated gate bipolar transistor (IGBT). The semiconductor element 40 is configured so that the amount of electric current flowing through a pair of input and output electrode plates 42 and 44 is controlled according to a control signal applied to a control electrode 46. A semiconductor material of the semiconductor element 40 is not particularly limited, but may be, for example, silicon (Si), silicon carbide (SiC), gallium nitride (GaN), or gallium oxide (Ga₂O₃).

The molded resin 50 covers the graphite plate 20, the metal plate 30, and the semiconductor element 40, which are disposed above the insulating plate 10, and also covers the side surface of the insulating plate 10. Referring to the insulating plate 10 in detail, the molded resin 50 covers the extension portion 14 of the insulating plate 10 in such a manner that the molded resin 50 is in contact with the upper surface and the side surface of the extension portion 14, as shown in FIG. 2. Since the molded resin 50 is provided so as to include the corner between the upper surface and the side surface of the extension portion 14 of the insulating plate 10 in the covering area, peeling of the molded resin 50 is effectively suppressed.

In the semiconductor module 1, as described above, the insulating plate 10 and the graphite plate 20 are joined to each other, and the graphite plate 20 and the metal plate 30 are joined to each other. The insulating plate 10, the graphite plate 20 and the metal plate 30 are provided as an integral body, and serve as an integral heat dissipation substrate. For example, in a semiconductor module to which an insulating plate is attached externally, it is necessary to interpose grease with a low thermal conductivity between the insulating plate and the semiconductor module. In such a case, there is a fear that the heat dissipation characteristics are insufficient. In the semiconductor module 1 of the present embodiment, on the other hand, the insulating plate 10, the graphite plate 20 and the metal plate 30 form the integral structure as the heat dissipation substrate, and no grease is interposed between the insulating plate 10 and the graphite plate 20. Therefore, the semiconductor module 1 can have high heat dissipation characteristics.

In the semiconductor module 1, the insulating plate 10 extends over the graphite plate 20, that is, extends from the graphite plate 20 in the plan view. For this reason, a creepage distance at the insulating plate 10 is kept long, so that the creepage leak current along the insulating plate 10 is suppressed.

The features of the techniques disclosed in the present disclosure are summarized hereinafter. It should be noted that the technical elements described hereinafter are independent technical elements and exhibit technical usefulness alone or in various combinations, and may be combined in various ways.

In the present disclosure, a semiconductor module can include an insulating plate, a graphite plate and a semiconductor element. The graphite plate is made of a plurality of graphene layers stacked on top of another. The graphite plate has a first surface joined to the insulating plate, and a second surface opposite to the first surface. The semiconductor element is disposed adjacent to the second surface of the graphite plate. The insulating plate extends from the graphite plate in a plan view in a direction normal to the insulating plate.

In the semiconductor module described above, the insulating plate may be brazed to the first surface of the graphite plate. Such a semiconductor module can have high heat dissipation characteristics.

The semiconductor module may further include a metal plate joined to the second surface of the graphite plate, and on which the semiconductor element is mounted. Furthermore, the metal plate may be brazed to the graphite plate. In such a semiconductor module, an integral heat dissipation substrate is provided by the insulating plate, the graphite plate, and the metal plate. In other words, the insulating plate, the graphite plate and the metal plate are integrated into a unit and provide the heat dissipation substrate. Therefore, this semiconductor module can have high heat dissipation characteristics.

The semiconductor module may further include a molded resin covering the graphite plate and the semiconductor element, as well as the side surface of the insulating plate. In such a semiconductor module, peeling or separation of the molded resin is effectively suppressed.

Although specific examples of the present disclosure have been described in detail above, these are merely examples and do not limit the scope of claims. The techniques described in the claims include various modified examples and modified examples of the specific examples illustrated above. In addition, the technical elements described in the present specification or the drawings exhibit technical usefulness alone or in various combinations, and are not limited to the combinations described in the present description at the time of filing. In addition, the techniques illustrated in the present specification or drawings can achieve multiple purposes at the same time, and achieving one of the purposes itself has technical usefulness.

What is claimed is:

1. A semiconductor module comprising:
an insulating plate;
a graphite plate provided by a stack of graphene layers, the graphite plate having a first surface joined to the insulating plate, and a second surface opposite to the first surface; and
a semiconductor element disposed adjacent to the second surface of the graphite plate, wherein
the insulating plate extends from the graphite plate in a plan view in a direction normal to the graphite plate.

2. The semiconductor module according to claim 1, wherein
the first surface of the graphite plate is brazed to the insulating plate.

3. The semiconductor module according to claim 2, further comprising:
a metal plate disposed on the second surface of the graphite plate, wherein
the metal plate is brazed to the second surface of the graphite plate.

4. The semiconductor module according to claim 1, further comprising:
a metal plate disposed on the second surface of the graphite plate, wherein
the metal plate is brazed to the second surface of the graphite plate.

5. The semiconductor module according to claim 1, further comprising:
a molded resin that covers the graphite plate, the metal plate, the semiconductor element, and a side surface of the insulating plate.

6. The semiconductor module according to claim 2, further comprising:
a molded resin that covers the graphite plate, the semiconductor element, and a side surface of the insulating plate.

7. The semiconductor module according to claim 3, further comprising:
a molded resin that covers the graphite plate, the metal plate, the semiconductor element, and a side surface of the insulating plate.

8. The semiconductor module according to claim 4, further comprising:
a molded resin that covers the graphite plate, the metal plate, the semiconductor element, and a side surface of the insulating plate.
